(19) United States
(12) Patent Application Publication
(10) Pub. No.: US 2009/0233537 A1
(43) Pub. Date: Sep. 17, 2009

(54) Air baffle and calculation method of deformational stress thereof

(75) Inventors: Cheng-Sen Kao, Taipei (TW); Wen-Lan Yang, Taipei (TW); Ren-Jeng Lin, Taipei (TW)

Correspondence Address: Workman Nydegger;1000 Eagle Gate Tower, 60 East South Temple, Salt Lake City, UT, 84111, US

(73) Assignee: Inventec Corporation, Taipei (TW)

(21) Appl. No.: 12/151,072

(22) Filed: May 2, 2008

(30) Foreign Application Priority Data
Mar. 14, 2008 (TW) 097109156

(51) Int. Cl. H05K 7/20; H05K 5/00

(52) U.S. Cl. 454/184; 361/695

(57) ABSTRACT

An air baffle has elasticity and is disposed in an electronic device. The air baffle may be elastically deformed under a pressure exerted by an article. The air baffle includes a fixed section and at least one deformable section extending from a lateral side of the fixed section. The deformable section is arc-shaped and has a second-order deformation. A deformational stress of the deformable section is calculated using

$$σ = \frac{FR ( sin θ ) t}{2 I} ,$$

and an allowable radius of curvature of the deformable section is determined, so as to keeping the deformational stress of the deformable section not exceeding a material yield stress of the air baffle.

### CROSS-REFERENCE TO RELATED APPLICATIONS

This non-provisional application claims priority under 35 U.S.C. §119(a) on Patent Application No(s). 097109156 filed in Taiwan, R.O.C. on Mar. 14, 2008, the entire contents of which are hereby incorporated by reference.

### BACKGROUND OF THE INVENTION

1. Field of Invention

The present invention relates to an air baffle, in particular, to an air baffle having a second-order deformation and a calculation method of a deformational stress thereof.

2. Related Art

In order to satisfy consumers' demands for higher data processing speed of computer systems so as to achieve booting various programs in a very short time, persons in this art usually increase the precision of the chips to improve the processing speed and the development of multiplex operation. Along with the advancement of the processing speed of the computer systems, in the trend of miniaturization of the electronic devices, the problem of high heat generation of the computer devices inevitably occurs.

If the thermal cannot be dissipated in time, the over high temperature may severely influence the stability and efficiency of operation of the chips or electronic processing units, and even reduce the service life or damage the computer devices. Therefore, how to quickly dissipate the thermal generated by the operation processing units is in need of solution urgently.

For a 1U blade server, when the memory unit in the server is operating, the ventilation of the thermal dissipation airflow flow is unsatisfactory due to the limited space inside the server. Thus, the memory unit may be overheated, leading to a low performance or even damage.

As shown in FIGS. 1 and 2, in order to solve the thermal dissipating problem in the 1U server, an air baffle 10 supported on the bottom of the circuit board 22 is mounted on a back plate 21 of a server 20. The conventional air baffle 10 includes a fixed section 11, a connecting section 12, a bent section 13, and an urging section 14. The connecting section 12, the bent section 13, and the urging section 14 successively extends from the two opposite lateral sides of the fixed section 11. The fixed section 11 is fixed on the back plate 21, the urging section 14 bears the circuit board 22, and the connecting section 12 and the bent section 13 provide an elastic deformation range of the air baffle 10, such that a memory unit (not shown) may be accommodated in the space of the server 20.

Since the air baffle must have elasticity so as to restore its original state after being deformed under a pressure, the selection of size and material of the air baffle must take the condition that the stress of the deformed air baffle cannot exceed the yield stress of the selected material into account, so as to ensure the deformation mode of the air baffle is an elastic deformation mode, and prevent the permanent deformation of the air baffle.

FIGS. 3 and 4 show analysis results of elasticity and plasticity simulation of a finite element of a stainless steel (model No. SUS301) and Ti alloy. It is known from FIG. 3 that after the air baffle made of the conventional stainless steel SUS301 is compressed, the deformational stress exerted on the connecting section has exceeded the yield stress (the yield stress is 965 MPa) of stainless steel SUS301. As shown in FIG. 4, even if the air baffle is made of Ti alloy (the yield stress of the Ti alloy is 1140 MPa), the problem of the permanent deformation generated after the air baffle is compressed cannot be solved, and the air baffle can merely be compressed downwardly for 18.4 mm. Thus, the formed space is insufficient for accommodating the memory unit.

The conventional air baffle is usually in the form of a first-order arm. Even if the Ti alloy having a higher yield stress is adopted, the problem that the deformational stress of the air baffle easily exceeds the yield stress of the material thus further causing a permanent deformation of the air baffle cannot be solved. Therefore, how to design the air baffle kept in an elastic deformation mode is in need of solution urgently.

### SUMMARY OF THE INVENTION

In view of the above problem, the present invention provides an air baffle and a calculation method of a deformational stress thereof, so as to solve the problem that the elastic deformation range of the first-order arm type air baffle cannot meet the requirement in use of the server, and the deformational stress may cause a permanent deformation of the air baffle caused by the relative increasing of deformation in the conventional art.

The air baffle of the present invention has elasticity and is disposed in an electronic device. The air baffle is capable of being elastically deformed under a pressure exerted by an article. The air baffle includes a fixed section and at least one deformable section extending from a lateral side of the fixed section. The deformable section is arc-shaped and has a second-order deformation. A deformational stress of the deformable section is calculated using

$$σ = \frac{FR ( sin θ ) t}{2 I} ,$$

and an allowable radius of curvature of the deformable section. In the equation, σ is the deformational stress of the deformable section, I is a moment of inertia, F is a maximum external force exerted on the deformable section by the article, R is the allowable radius of curvature of the deformable section, θ is an angle formed between two ends of the deformable section and a center of the radius of curvature of the deformable section, and t is a thickness of the air baffle. Based on the above equation, the deformational stress of the deformable section is ensured to be not exceeding a material yield stress of the air baffle. Therefore, the deformation mode of the air baffle of the present invention maintains an elastic deformation mode.

The present invention provides a calculation method of the deformational stress of the air baffle, which includes the following steps. Firstly, a material is selected, and a material thickness t and an allowable radius R of curvature are determined, such that the material assumes an arc shape. The angle θ formed between two ends of the arc of the material and the center of the allowable radius of curvature is determined according to the allowable radius R of curvature of the material. Then, the maximum external force F exerted on the material by the article is determined, and the moment of inertia I of the material is calculated. Finally, the deformational stress σ of the material is calculated using

$$σ = \frac{FR ( sin θ ) t}{2 I} .$$

In the present invention, a dynamic deformational stress of the air baffle under a pressure exerted by the article is calculated based on the above equation, and the deformable section of the air baffle is designed to have an arc shape with a second-order deformation, so that the maximum deformational stress of the air baffle will not exceed the material yield stress, thereby preventing the permanent deformation of the air baffle.

### BRIEF DESCRIPTION OF THE DRAWINGS

The patent or application file contains at least one drawing executed in color. Copies of this patent or patent application publication with color drawings will be provided by the Office upon request and payment of the necessary fee.

The present invention will become more fully understood from the detailed description given herein below for illustration only, and thus are not limitative of the present invention, and wherein:

FIG. 1 is a perspective view of a conventional air baffle;

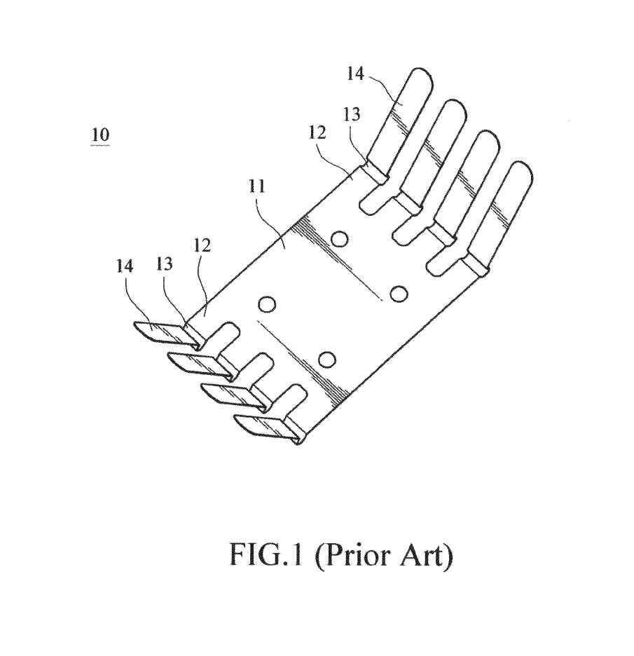

FIG. 2 is a perspective view of a conventional electronic device having the air baffle;

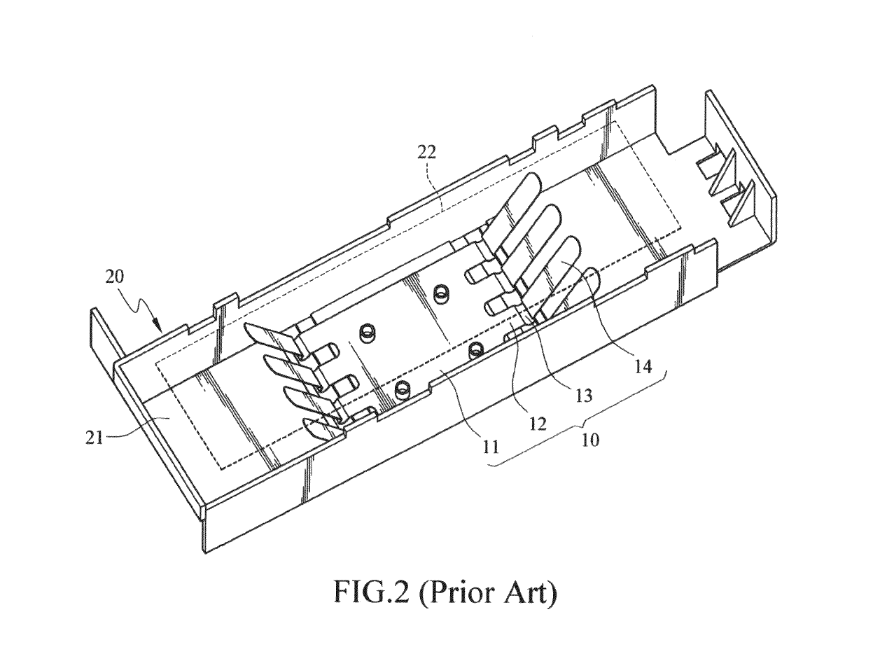

FIG. 3 is a schematic view of a simulation test of the conventional air baffle;

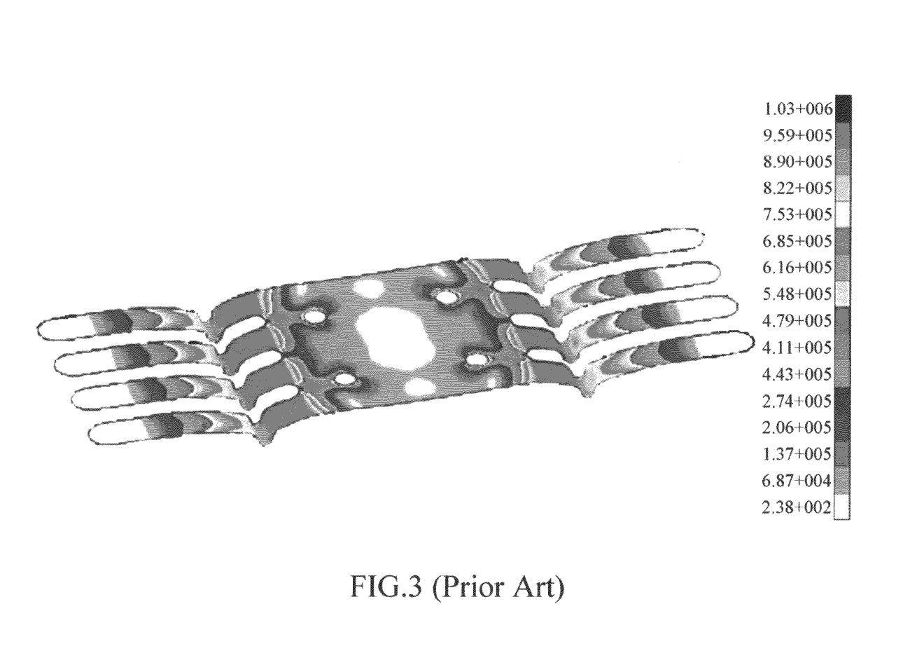

FIG. 4 is a schematic view of a simulation test of the conventional air baffle;

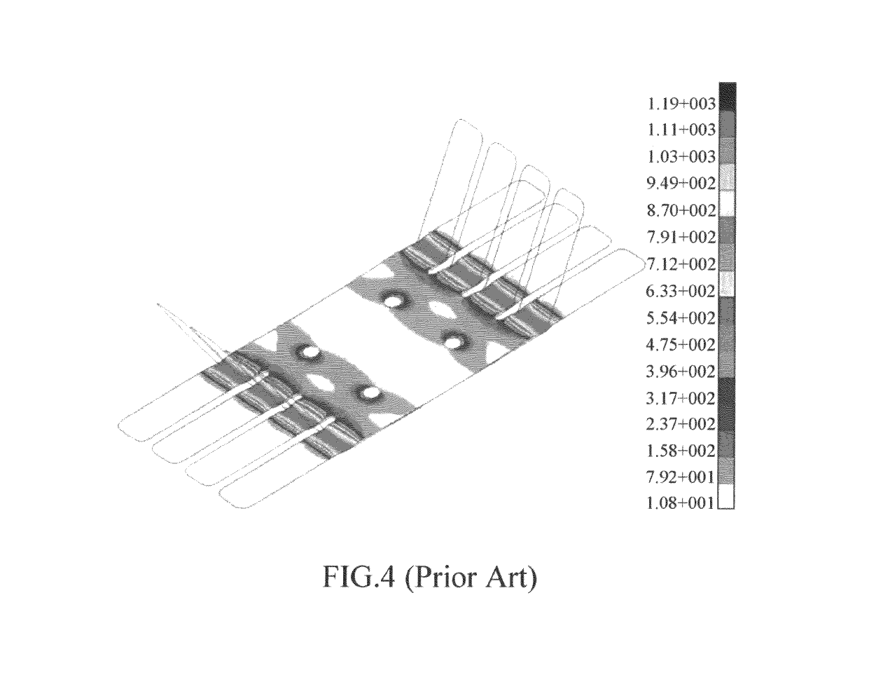

FIG. 5 is a perspective view of an air baffle of the present invention;

FIG. 6 is a perspective view of an electronic device having the air baffle of the present invention;

FIG. 7 is a flow chart of steps of calculating a deformational stress of the air baffle of the present invention;

FIG. 8 is a schematic view of a simulation test of the air baffle of the present invention; and

FIG. 9 is a relation diagram of a radius of curvature and a deformational stress of the air baffle of the present invention.

### DETAILED DESCRIPTION OF THE INVENTION

The air baffle of the present invention is mounted in an electronic device which likes a computer device, such as a desktop computer, a notebook computer, and a server, but not limit to the above-mentioned computer devices. In the following detailed description of the present invention, the server is taken as an example for illustrating the present invention. However, the drawings are merely provided for reference and illustration instead of limiting the present invention.

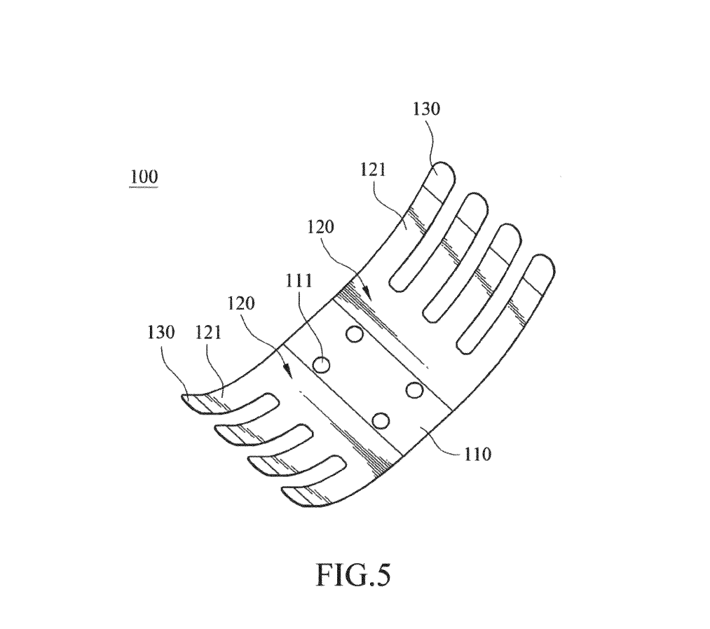

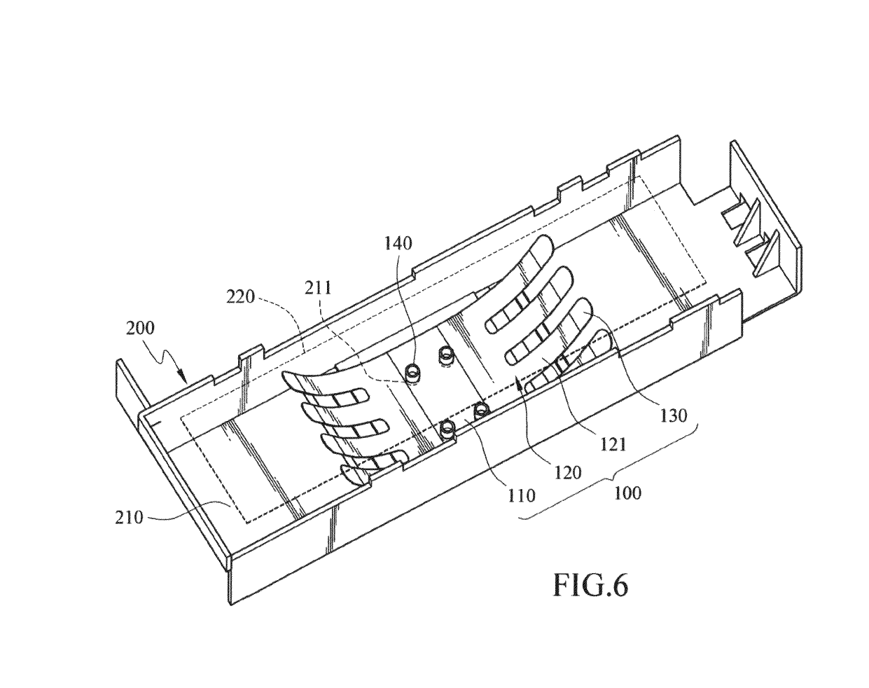

As shown in FIGS. 5 and 6, the air baffle 100 of the present invention has elasticity and is mounted in an electronic device 200. The electronic device 200 has a back plate 210 and an article 220, the article 220 is placed on the air baffle 100, and the air baffle 100 may be elastically deformed under a pressure exerted by the article 220. The article 220 of the present invention is, for example, but is not limited into, a circuit board in the embodiments.

The air baffle 100 includes a fixed section 110 and two deformable sections 120 extending from two opposite lateral sides of the fixed section 110, so that the air baffle 100 of the present invention forms a symmetrical structure. The fixed section 110 has at least one fixing hole 111, and the back plate 210 of the electronic device 200 has a joining hole 211 corresponding to the fixing hole 111. A locking member 140 such as a bolt, a latch, and a rivet passes through the fixing hole 111 and is locked in the joining hole 211, thereby fixing the fixed section 110 on the back plate 210.

Please refer to FIGS. 5 and 6, the deformable section 120 of the present invention has a plurality of arms 121 arranged separately. A support piece 130 extends from the other side of the arm 121 opposite to the fixed section 110 so as to support the bottom side of the article 220. The deformable section 120 is arc-shaped and has a second-order deformation, and a dynamic deformational stress of the deformable section 120 is calculated using the following equation (1), so as to keep the deformational stress of the deformable section 120 not exceeding a material yield stress of the air baffle 100:

$$σ = \frac{FR ( sin θ ) t}{2 I} \qquad ( 1 )$$

where, σ is a deformational stress of the deformable section 120, I is a moment of inertia of the deformable section 120, F is a maximum external force exerted on the deformable section 120 by the article 220, R is an allowable radius of curvature of the deformable section 120, θ is an angle formed between two ends of the deformable section 120 and a center of the radius of curvature of the deformable section 120, and t is a thickness of the air baffle 100. F in the above equation (1) is a relevant function of the deformation of the deformable section 120: F=f(Δ), and the equation (1) is deduced from the following equation (2):

$$σ = \frac{My}{I} \qquad ( 2 )$$

where, M is a bending moment of the deformable section 120, and M=FR sin θ, the values are substituted into equation (2) to obtain the equation (1).

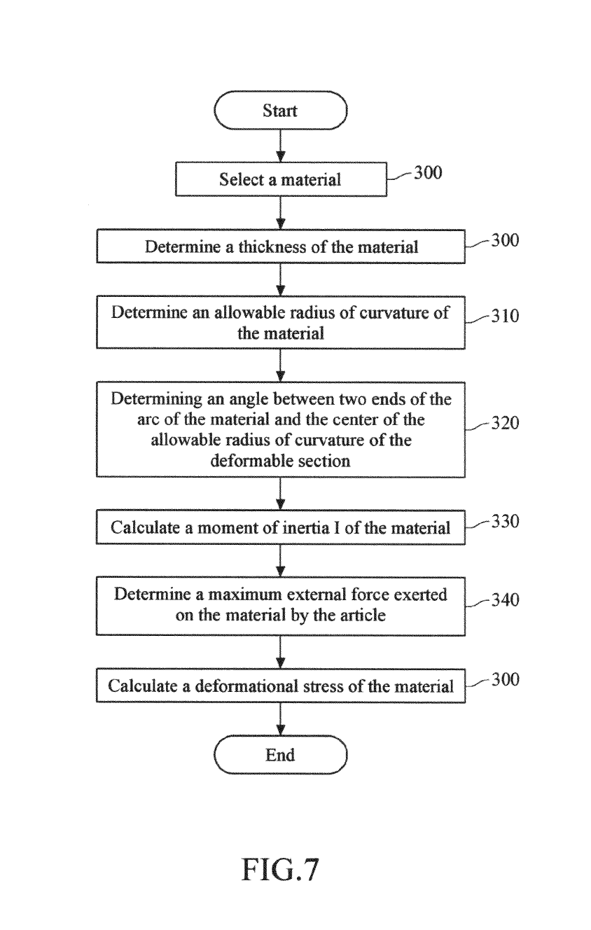

Referring to the flow chart of the steps in FIG. 7, the calculation method of the deformational stress of the air baffle of the present invention includes the following steps. Firstly, a material is selected as the material of the air baffle 100 (Step 300), so as to determine a material yield stress σ_{y} of the air baffle 100. The stainless steel SUS301 is selected for illustration in this embodiment of the present invention. However, persons skilled in the art may adopt other materials for making the air baffle 100, which is not limited to this embodiment. Then the thickness t of the material is determined (Step 310), and the allowable radius R of curvature of the material is determined, such that the deformable section 120 of the air baffle 100 is formed arc-shaped (Step 320). The angle θ formed between two ends of the deformable section 120 and a center of the radius of curvature of the deformable section is determined according to the allowable radius R of curvature of the material (Step 330). Then, the moment of inertia I of the deformable section 120 is calculated (Step 340), and then the maximum external force exerted on the deformable section 120 by the article 220 (for example, a circuit board in this embodiment) in the electronic device 200 is determined (Step 350). Finally, the above designed parameters are substituted into the equation (1):

$$σ = \frac{FR ( sin θ ) t}{2 I}$$

so as to calculate the deformational stress of the deformable section 120 (Step 360), thereby ensuring the deformational stress σ of the deformable section 120 not exceeding the yield stress σ_{y} of the material of the air baffle 100.

It should be noted that, the order of the above Steps 310, 320, 330, 340, and 350 in the present invention may be changed according to the actual calculation process, and is not limited to the order disclosed in this embodiment. In the present invention, the allowable radius R of curvature of the deformable section 120 is determined, and the deformational stress is calculated using the equation (1), so as to ensure the deformational stress σ of the deformable section 120 not exceeding the material yield stress σ_{y} of the air baffle 100.

If the deformational stress ay calculated using the equation (1) exceeds the material yield stress σ_{y}, the radius R of curvature of the air baffle 100 is adjusted, so as to prevent the deformational stress σ of the deformable section 120 from exceeding the material yield stress σ_{y} to cause the permanent deformation of the air baffle 100. However, the present invention may also adjust other design parameters of the air baffle 100, such as the maximum external force F exerted on the deformable section 120 by the article 220, or the thickness t of the air baffle 100, which is not limited to the adjustment of the radius R of curvature of the deformable section 120.

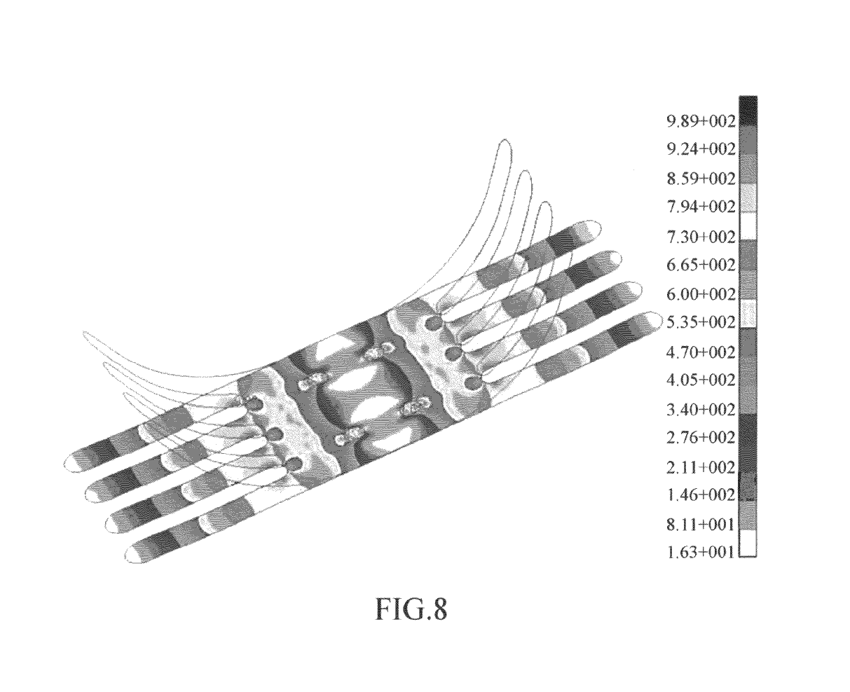

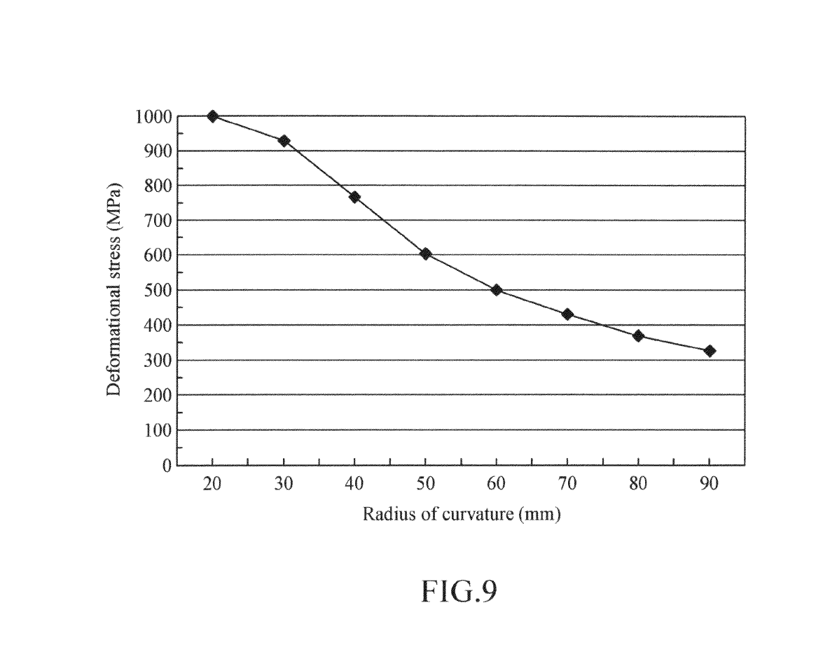

As shown in FIGS. 8 and 9, the stainless steel SUS301 is used in the present invention for making the air baffle 100. It can be known from the analysis results of elasticity and plasticity simulation that, when the deformable section 120 suffers a continuous force, the arm 121 extends outwardly so as to reduce the suspending distance of the arm 121. Meanwhile, the deformational stress of the arm 121 is reduced to compensate the increased deformational stress due to the increased deformation of the arm 121 connected to the fixed section 110. As shown in FIG. 9, according to the equation (1), when the minimum allowable radius of curvature of the deformable section 120 is designed to be 30 mm, the maximum deformational stress of the deformable section 120 will not exceed the material yield stress (965 MPa) of stainless steel SUS301. When the pressure exerted on the deformable section 120 by the article 220 is increased, the radius R of curvature of the deformable section 120 is increased accordingly and the angle θ is reduced, and accordingly the deformational stress of the deformable section 120 is reduced according to a sin θ function. Moreover, it is known from FIG. 9 that, the effective radius of curvature of the deformable section 120 in the present invention is optimally 30 mm to 60 mm, so as to ensure the air baffle 100 in the elastic deformation mode, and prevent the air baffle 100 from producing the permanent deformation (plastic deformation).

In the present invention, the dynamic stress variant of the deformed air baffle is calculated using the equation (1), and the deformable section of the air baffle is designed to have an arc shape with a second-order deformation according to the equation (1). Thus, when a force is exerted on the deformable section by the article, the suspending length is reduced with the increase of the deformation, and the maximum deformational stress of the air baffle will not exceed the material yield stress, thereby preventing the permanent deformation of the air baffle.

What is claimed is:

1. An air baffle, having elasticity and capable of being elastically deformed under a pressure exerted by an article, wherein the air baffle is arc-shaped and has a second-order deformation.

2. An air baffle, disposed in an electronic device, having elasticity and capable of being elastically deformed under a pressure exerted by an article, wherein the air baffle comprises a fixed section and at least one deformable section extending from a side of the fixed section, and the deformable section is arc-shaped and has a second-order deformation.

3. An air baffle, disposed in an electronic device, having elasticity and capable of being elastically deformed under a pressure exerted by an article, wherein the air baffle comprises a fixed section and at least one deformable section extending from a side of the fixed section, the deformable section is arc-shaped and has a second-order deformation, and a deformational stress of the deformable section is calculated using a equation:
$$σ = \frac{FR ( sin θ ) t}{2 I}$$
where, σ is a deformational stress of the deformable section, I is a moment of inertia of the deformable section, F is a maximum external force exerted on the deformable section by the article, R is an allowable radius of curvature of the deformable section, θ is an angle formed between two ends of the deformable section and a center of the radius of curvature of the deformable section, and t is a thickness of the air baffle.

4. The air baffle according to claim 3, wherein the allowable radius of curvature of the deformable section is between 30 mm and 60 mm.

5. The air baffle according to claim 3, wherein the air baffle has two deformable sections symmetrically disposed at two opposite sides of the fixed section.

6. The air baffle according to claim 3, wherein the deformable section further comprises a plurality of arms arranged separately.

7. The air baffle according to claim 6, further comprising a plurality of support pieces respectively extending from the arms to other side of the fixed section, and supporting one side of the article.

8. The air baffle according to claim 3, wherein the fixed section comprises at least one fixing hole, the electronic device comprises at least one joining hole, and the fixing hole and the joining hole are combined by a locking member passing therethrough.

9. A calculation method of a deformational stress of an air baffle, wherein the air baffle has ela sticity and is capable of being elastically deformed under a pressure exerted by an article, the calculation method comprising:
selecting a material;
determining a thickness t of the material;
determining an allowable radius R of curvature of the material, so as to make the material being arc-shaped;
determining an angle θ formed between two ends of the arc of the material and a center of the allowable radius of curvature of the deformable section according to the allowable radius R of curvature of the material;
calculating a moment of inertia I of the material;
determining a maximum external force F exerted on the material by the article; and
calculating a deformational stress c of the material using
$$σ = \frac{FR ( sin θ ) t}{2 I} .$$
